(19) United States
(12) Patent Application Publication
(10) Pub. No.: US 2009/0009978 A1
(43) Pub. Date: Jan. 8, 2009

(54) Electric connection box and manufacturing method thereof

(75) Inventor: Hirohiko Fujimaki, Makinohara (JP)

Correspondence Address: Edwards Angell Palmer & Dodge LLP, P.O.Box 55874, Boston, MA, 02205, US

(73) Assignee: Yazaki Corporation, Tokyo (JP)

(21) Appl. No.: 12/213,637

(22) Filed: Jun. 23, 2008

(30) Foreign Application Priority Data
Jul. 5, 2007 (JP) 2007-177645

(51) Int. Cl. H05K 5/00; H01S 4/00

(52) U.S. Cl. 361/752; 29/592.1

(57) ABSTRACT

The present invention is to provide an inexpensive electric connection box and a manufacturing method thereof, which can reduce manufacturing process and a number of parts. The electric connection box has a bus bar arranged on another member different from the board, and a circuit element mounted on a board. A power source lead connected to an electric source is arranged on a part of the bus bar. Also, a semiconductor relay, which is electrically connected between the power source lead and a connector lead connected with a wire from a load, is mounted on the bus bar. A board supporting part for supporting the board and a bus bar supporting part for supporting the bus bar are arranged on a case body. The bus bar supporting part is provided on another area different from the board supporting part.

The priority application Number Japan Patent Application No. 2007-177645 upon which this patent application is based is hereby incorporated by reference.

### BACKGROUND OF THE INVENTION

1. Field of the Invention

The present invention relates to an electric connection box and a manufacturing method thereof, and particularly to an electric connection box controlling electric power supplied to a load and a manufacturing method thereof.

2. Description of the Related Art

So far, as an electric connection box in which a semiconductor relay such as an intelligent power switch (IPS) is used, an electric connection box in which a connector for connection and semiconductor relay are mounted on a board has been known. The connector connects the board to a load such as a headlamp, fog lamp and various motors. The semiconductor relay supplied electric power to a load according to instructions from the board. As mentioned above, in an electric connection box mounting a semiconductor relay on a board, the heat-releasing property is improved by releasing heat from the semiconductor relay. As a result, it is required that a heat-releasing plate is provided on a back surface of the board. Therefore, it is difficult to perform the heat-releasing property and miniaturization together.

Accordingly, an electric connection box 100 shown in FIG. 6 has been proposed so as to have a superior radiation performance and to downsize (patent documents 1 and 2). As shown in FIG. 6, this electric connection box 100 has a board 102 on which a circuit element 101 are mounted, a semiconductor relay module 103 and a housing 104. The semiconductor relay module 103 is arranged on another member different from the board 102, and mounted on the board 102. The housing 104 receives the board 102 and the semiconductor relay module 103. A die pad 105, a semiconductor relay 106, a power source lead 107, a connector lead 108 and a board lead 109 are connected to a lead frame in a chain shape. By sealing the lead frame into a resin mold part 110 and removing a chain part, the semiconductor relay module 103 is formed.

The above die pad 105 is made of conductive metal. The semiconductor relay 106 is mounted on the die pad 105. The power source lead 107 is arranged on part of the die pad 105, and electric power is supplied to the power source lead 107. A load is connected to the connector lead 108, and the board lead 109 is connected to the board 102. The semiconductor relay 106 is electrically connected to the power source lead 107 by a wire bonding 111, and also the semiconductor relay 106 is electrically connected to the board lead 109 by a wire bonding 111.

In the electric connection box 100 described above, the semiconductor relay 106 of high calorific power and the board 102 are formed from a different member. Furthermore, the board 102 does not have a wiring of electric source toward the semiconductor relay 106. Thereby, the electric connection box 100 can improve the hear-release characteristic and can downsize so that heat produced from the semiconductor relay 106 can be released through the connector lead 108. However, in the semiconductor relay module 103 descried above, the die pad 105 on which the semiconductor relay 106 is mounted is sealed into the resin mold part 110, and supported. As a result, various problems are caused as described below.

That is, the semiconductor relay 106 is protected by the resin mold part 110. Also, in order to protect the circuit element 101 mounted on the board 102, it is required to cover the circuit element 101 by protective film such as a silicone gel. Thereby, a protective film for protecting the circuit element 101 and the resin mold part 110 such as a protective film for protecting the semiconductor relay 106 should be provided in separate manufacturing process. As a result, a number of parts and manufacturing process be increased, and cause an increase in cost.

Furthermore, in the above mentioned electric connection box 100, it is required to mount the semiconductor relay module 103 on the board 102, and to solder the board lead 109 of the semiconductor relay module 103 on the board 102. Thereby, also this causes increases of manufacturing process and cost. In addition, since the semiconductor relay 106, the power source lead 107 and the connector lead 108 is formed integrally with the resin mold part 110, the housing 104 can not be molded in condition inserting the connector lead 108. Thereby, also this causes an increase of cost. Furthermore, when a terminal for supplying electric source is fit against the power source lead 107, it may give stress to the board 102.

Patent document 1:
Japan published patent application No. 2002-359349

Patent document 2:
Japan published patent application No. 2002-293201

### SUMMARY OF THE INVENTION

### Objects to be Solved

It is therefore an objective of the present invention to solve the above problems and to provide an electric connection box and a manufacturing method thereof, by which a board can be protected, and by which a manufacturing process and parts can be reduced.

### How to Attain the Object of the Present. Invention

According to a first aspect of the present invention, an electric connection box includes a board having a circuit element mounted thereon, a bus bar, an electric source lead, a connector lead connected to a load, a semiconductor relay and a housing. The bus bar is arranged on a member different from the board and made of a conductive member in a plate shape. The electric source lead is arranged on the bus bar, and an electric source is supplied to the electric source lead. The semiconductor relay is electrically connected between the electric source lead and the connector lead, and is mounted on the bus bar. The housing has a board supporting part for supporting the board, and a bus bar supporting part for supporting the bus bar. The bus bar supporting part is arranged on another area different from the board supporting part.

According to a second aspect of the present invention, the circuit element is mounted on an upper face of the board, the semiconductor relay is mounted on an upper face of the bus bar, and both the circuit element and the semiconductor relay are covered with a protective film of a same member each other.

According to a third aspect of the present invention, the electric connection box further includes a wire. One end of the wire is connected to the semiconductor relay, and the other end of the wire is connected to the board.

According to a fourth aspect of the present invention, the board and the bus bar is arranged in the same place each other.

According to a fifth aspect of the present invention, the bus bar is formed integrally with the housing.

According to a sixth aspect of the present invention, a manufacturing method of an electric connection box includes the steps of: injecting a molten member of a housing into a forming die of the housing in condition that a bus bar formed with a conductive member of a plate shape is inserted in the forming die, and molding the housing, mounting a semiconductor relay on the bus bar, attaching a board on which a circuit element is mounted to the housing, and connecting the semiconductor relay to the board by a wire and further connecting the semiconductor relay to a connector lead by a wire.

### EFFECT OF THE INVENTION

According to the invention, even if a terminal for electric supply is fit and connected to the electric source lead, stress have no effect on the board. Thereby, the board can be protected. Also, it is not necessary to provide the electric connection box with a resin mold part. As a result, protective films for protecting the circuit element and the semiconductor relay can be provided in the same process. Furthermore, since the resin mold part is not required, the semiconductor relay and the board can be connected by a wire. Thereby, there is no necessity to arrange the board lead on the board, and to solder the board load on the board as before. In addition, the housing can be molded in condition that the bus bar is inserted into the housing. Therefore, manufacturing process and a number of parts can be reduced, and a cheap electric connection box can be provided.

According to the invention, since the protective film for protecting the circuit element and the protective film for protecting the semiconductor relay can be formed with a same process, providing a wire between the semiconductor relay and the board is easier. Thereby, manufacturing process can be reduced, and an inexpensive electric connection box can be produced.

According to the invention, since the housing and the bus bar can be formed integrally, manufacturing process and a number of parts can be reduced. Consequently, an inexpensive electric connection box can be manufactured.

The above and other objects and features of this invention will become more apparent from the following description taken in conjunction with the accompanying drawings.

### BRIEF DESCRIPTION OF THE DRAWINGS

FIG. 1 is a plan view showing an embodiment of an electric connection box of the present invention;

FIG. 2 is a sectional view taken along a line A-A in FIG. 1;

FIG. 3 is an illustration view from arrow P1 of the electric connection box shown in FIG. 1;

FIG. 4 is an illustration view from arrow P2 of the electric connection box shown in FIG. 1;

FIG. 5 is an exploded perspective view of the electric connection box shown in FIG. 1; and

FIG. 6 is a plan view showing one embodiment of a conventional electric connection box by prior art.

### DESCRIPTION OF THE PREFERRED EMBODIMENT

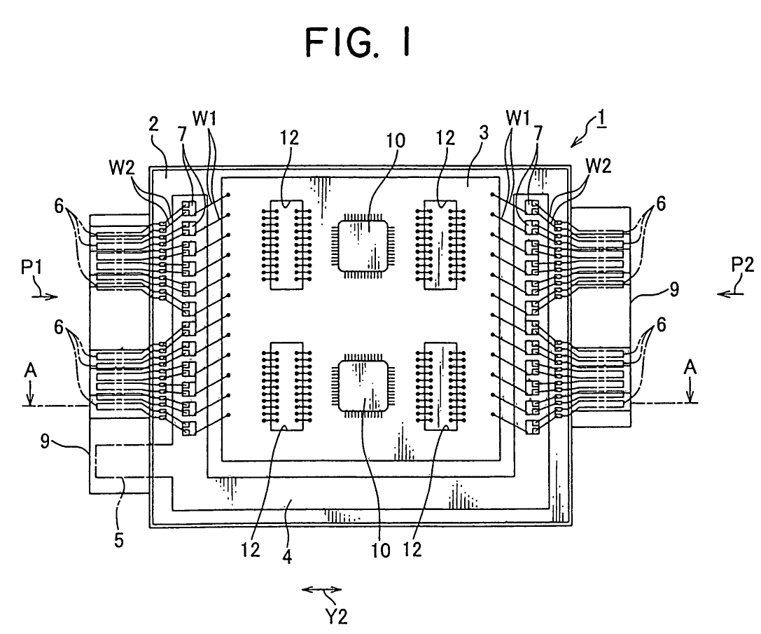

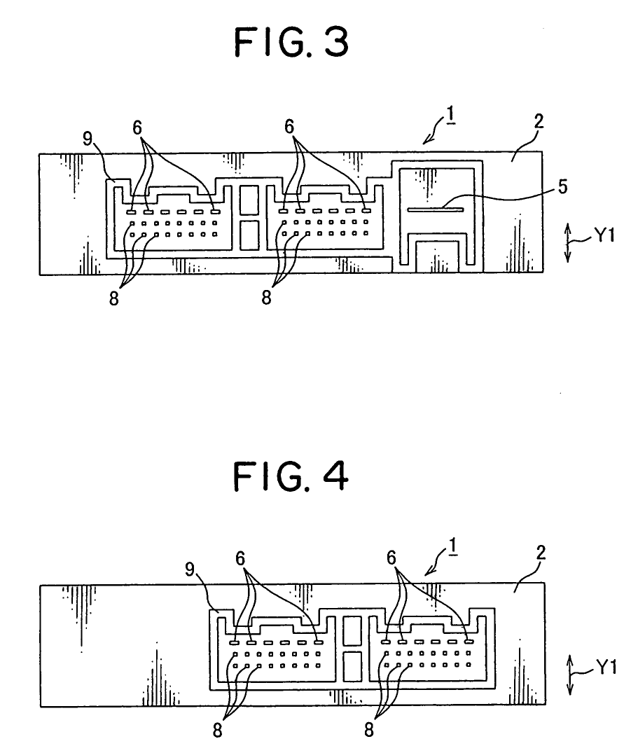

In the following, the preferred embodiments of the present invention are explained with reference to FIGS. 1-5. FIG. 1 shows internal parts of an electric connection box 1 removing a cover. As shown in FIG. 1, the electric connection box 1 includes a case body 2 as a housing, a board 3, a bus bar 4, a power source lead 5, a plurality of connector leads 6, a plurality of semiconductor relays 7 and a plurality of control leads 8.

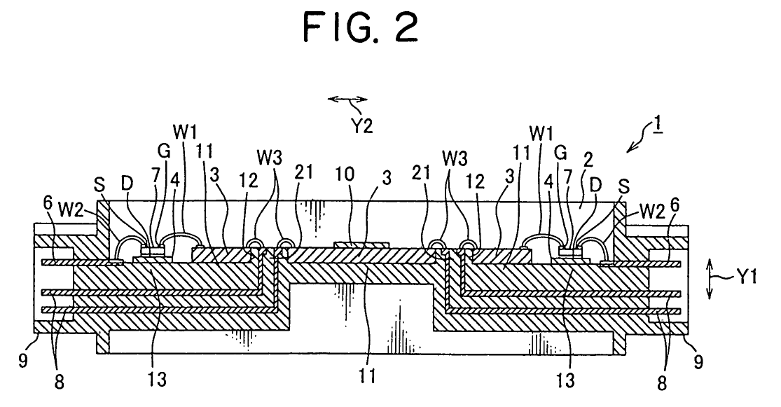

The above case body 2 opens upwardly (one side) in an orthogonal direction Y1 (FIG. 2) perpendicular to the board 3 and the bus bar 4, and is formed into a rectangular tray-shape. The case body 2 is made of electrically insulating material having a good hear-release characteristic. The case body 2 receives the board 3, the bus bar 4, the power source lead 5, the connector lead 6, the semiconductor relay 7 and the control lead 8 in the inside of the case body 2.

As shown in FIG. 2, in the case body 2, tubular hoods 9 are projected on both sides of a horizontal direction Y2. The power source lead 5, the connector lead 6 and the control lead 8 are received in the hood 9. The hood 9 fits a connector which receives an external terminal connecting the above power source lead 5, the connector lead 6 and the control lead 8.

The above board 3 is formed into a rectangular shape. The board 3 is mounted on a board supporting part 11 arranged in the center of a bottom face of the above case body 2, and supported by the board supporting part 11. In this board 3, a circuit element 10 such as a control microcomputer is mounted on opening side of the case body 2. That is, the circuit element 10 is mounted on an upper surface (one side) of the orthogonal direction Y1. Also, a wiring pattern (not shown) which is connected to the circuit element 10 and having a circuit is formed in the board 3. When the board 3 is mounted on the board supporting part 11, the exposure hole 12 fits with a projection 21 arranged on the case body 2.

The bus bar 4 is formed with a conductive member of a plate shape, and is arranged on another member different from the board 3. As shown in FIG. 1, the bus bar 4 is formed into a U-shaped shape surrounding three edges of outer edge of the board 3 of a square shape. Two edges of the bus bar 4 are arranged between the board 3 and the hoods 9 attached to each edge of the horizontal direction Y2 in the bottom face of the case body 2. A plurality of semiconductor relays 7 are mounted on the two edges of the bus bar 4. The third edge of the bus bar 4 connects portions on which the semiconductor relay 7 is mounted. That is, the third edge of the bus bar 4 connects one edge of the bus bar 4 on which the above semiconductor relay 7 is mounted to another edge of the bus bar 4 on which the above semiconductor relay 7 is mounted.

As shown in FIG. 2, a bus bar supporting part 13 for supporting the bus bar 4 on another area different from the board supporting part 11 is arranged on the bottom face of the case body 2. The above mentioned board supporting part 11 and the bus bar supporting part 13 are arranged in one plate. Thereby, the board 3 and the bus bar 3 are arranged in one plate.

For example, the power source lead 5 fits in an external terminal connected to the power source through a fuse (not shown). The power source lead 5 is arranged on a part of the above bus bar 4, and is received into the left-side hood 9 of the horizontal direction Y2. The connector lead 6 is formed into an elongate shape and a plate shape. Each one end of a plurality of connector leads 6 are exposed between the hood 9 and the bus bar 4, and each the other end is received into the hood 9 and inserted into the case body 2. Thereby, the connector lead 6 is supported. Furthermore, each the plate-shaped connector lead 6 is arranged in parallel to the board 3 and the bus bar 4.

As shown in FIG. 1, the plurality of semiconductor relays 7 are side by side arranged on area which is provided between the board 3 on the bus bar 4 and the hood 9. As shown in FIG. 2, the semiconductor relay 7 is mounted on an upper surface of the orthogonal direction Y1 of the bus bar 4. The semiconductor relay 7 has a drain electrode D arranged on a lower surface of the orthogonal direction Y1, that is a lower surface of the semiconductor relay 7. When the semiconductor relay 7 is mounted on the bus bar 4 which the drain electrode D faces, the drain electrode D of the semiconductor relay 7 is electrically connected to the power source through the bus bar 4.

Also, the semiconductor relay 7 has two source electrodes S and a gate electrode G in an upper side of the orthogonal direction Y1. The gate electrode G of the semiconductor relay 7 is electrically connected to the board 3 by a first wire W1. The source electrode S of the semiconductor relay 7 is electrically connected to the connector lead 6 by a second wire W2.

Thereby, the gate electrode G is connected to the circuit element 10 through the first wire W1, and the source electrode S is connected to a load through the second wire W2 and the connector lead 6. In addition, the drain electrode D is connected to the power source through the bus bar 4 and the power source lead 5. When the circuit element 10 outputs an ON signal to the gate electrode G of the semiconductor relay 7, an electric power is passed between the drain electrode D and the source electrode S. And then, the power source is supplied to the load.

The control lead 8 is formed into a conductive bar shape. One end of the control lead 8 is exposed from the projection 21 of the case body 2, and the other end is received into the hood 9 and inserted into the case body 2. By exposing one end of the control lead 8 from the projection 21 of the case body 2, one end of the control lead 8 is exposed from the exposure hole 12. The above one end of the control lead 8 is electrically connected to the board 3 by a third wire W3.

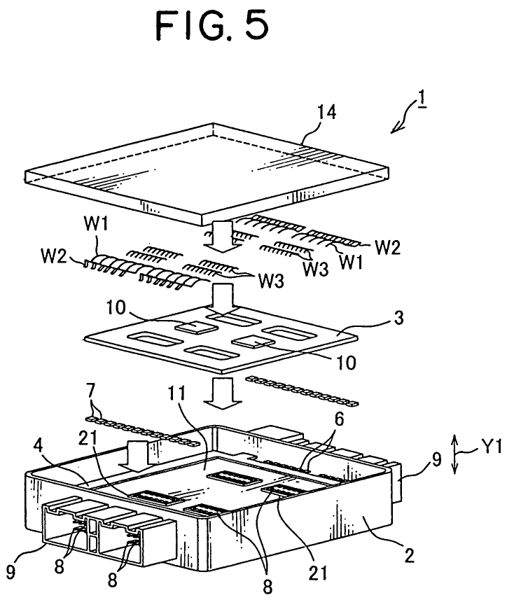

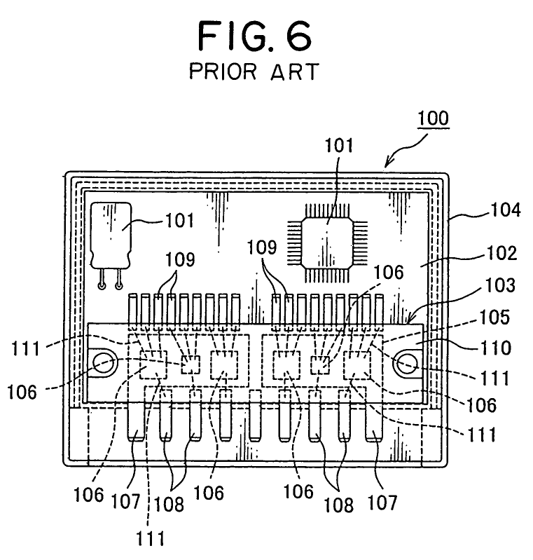

A manufacturing method of the above mentioned electric connection box 1 is explained with reference to FIG. 5. First, in condition that the bus bar 4, the connector lead 6 and the control lead 8 are inserted into a forming die (not shown) of the case body 2, the case body 2 is molded by injecting a molten member of the case body into the forming die. By this insert molding, the bus bar 4, the connector lead 6 and control lead 8 are molded into the case body 2.

Next, the semiconductor relay 7 is mounted on the bus bar 4. In particular, the semiconductor relay 7 is mounted by applying a paste adhesive (for example, solder or Ag paste) to an area on which the semiconductor relay 7 of the bus bar 4 is mounted. Thereafter, the area is hardened by heating. Thereby, the drain electrode D of the semiconductor relay 7 and the bus bar 4 connect electrically. Then, the board 3 mounting the circuit element 10 is assembled on the board supporting part 11 of the case body 2. Thereafter, the gate electrode G of the semiconductor relay 7 bonds to the board 3 by the first wire W1, the source electrode S of the semiconductor relay 7 bonds to the connector lead 6 by the second wire W2, and the board 3 bonds to the control lead 8 by the third wire W3.

And then, a protective film 14 is formed by filling silicone gel from an upper side of the orthogonal direction Y1. The protective film 14 protects the semiconductor relay 7 mounted on the bus bar 4 and the circuit element 10 mounted on the board 3. Thereby, the circuit element 10 and the semiconductor relay 7 are covered with the protective film 14 of a same member each other. After, the electric connection box 1 is completed by attaching a cover to an opening arranged on the upper side of the orthogonal direction Y1.

According to the above mentioned electric connection box 1, the semiconductor relay 7 of high calorific value is arranged on the bus bar 4 mounted on another member different from the board 3, and the bus bar 4 is mounted near a side of the hood 9. Thereby, heat produced from the semiconductor relay 7 is released directly from the connector lead 6 to an outer side without a passing through the board 3. As a result, it is not required to arrange a radiator plate on the board 3. Therefore, the electric connection box can downsize and can reduce parts of member.

Furthermore, according to the above mentioned electric connection box 1, since the bus bar supporting part 13 for supporting the bus bar 4 with another area differing from the board supporting part 11 is arranged on the case body 2, the bus bar 4 can be supported on the case body 2. Thereby, it is unnecessary to seal the bus bar 4 and the board lead by a resin mold part and to solder the board lead into the board 3 such as a conventional apparatus. Therefore, the protective film 14 for protecting the circuit element 10 and the semiconductor relay 7 can be manufactured with a same process.

Additionally, the semiconductor relay 7 and the board 3 can connect by the first wire W1. Thereby, it is not required to arrange the board lead as a conventional apparatus, and to solder the board lead to the board 3. Also, since the case body 2 can be molded in condition inserting the bus bar 4, manufacturing process and parts of the electric connection box can be reduced. Thereby, the inexpensive electric connection box 1 can be provided.

According to the above mentioned electric connection box 1 and manufacturing method thereof, since the case body 2 is formed by injecting the molten member of the case body 2 into the forming die in condition that the bus bar 4, the connector lead 6 and the control lead 8 is inserted into the forming die of the case body 2, the case body 2 and the bus bar 4 can be formed together.

According to the above embodiment, the circuit element 10 and the semiconductor relay 7 are arranged on the upper side of the orthogonal direction Y1 (one side), and a forming process of the protective film 14 is performed with a same process. However, the present invention is not limited thereto. For example, when it is not required to perform with a same process, the circuit element 10 can be arranged on a lower side of the orthogonal direction Y1.

Also, according to the above embodiment, the board 3 and the bus bar are arranged on one plate each other. However, the present invention is not limited thereto. For example, a step can be arranged between the board 3 and the bus bar 4. Therefore, it can be unnecessary to arrange the board 3 and the bus bar 4 in the same plate.

According to the above embodiment, in condition that the bus bar 4 is inserted into the forming die of the case body 2, the case body 2 is formed by injecting the molten member of the case body 2 into the forming die. However, the present invention is not limited thereto. For example, after forming the case body 2, the bus bar 4 can be attached to the case body 2.

According to the above embodiment, the power source is supplied to the load from the connector lead 6 of the semiconductor relay 7. However, the present invention is not limited thereto. For example, an H/L signal or a status signal (control signal) outputted from the circuit element 10 can be supplied from the connector lead 6.

The embodiments of the present invention are only exemplary and not limited thereto. Any modification and alteration are within the scope of the present invention.

What is claimed is:

1. An electric connection box comprising:
a board having a circuit element mounted thereon;
a bus bar arranged on a member different from the board and made of a conductive member in a plate shape;
an electric source lead arranged on a part of the bus bar provided with an electric source;
a connector lead connected to a load;
a semiconductor relay electrically connected between the electric source lead and the connector lead, and mounted on the bus bar; and
a housing providing a board supporting part for supporting the board,
wherein a bus bar supporting part for supporting the bus bar is provided on another area different from the board supporting part, and arranged on the housing.

2. The electric connection box as claimed in claim 1, wherein the circuit element is mounted on an upper face of the board, the semiconductor relay is mounted on an upper face of the bus bar, and both the circuit element and the semiconductor relay are covered with a protective film of a same member each other.

3. The electric connection box as claimed in claim 1, further comprising a wire, wherein one end of the wire is connected to the semiconductor relay, and the other end of the wire is connected to the board.

4. The electric connection box as claimed in claim 1, wherein the board and the bus bar are arranged on one plane each other.

5. The electric connection box as claimed in claim 1, wherein the bus bar is formed integrally with the housing.

6. A manufacturing method of an electric connection box comprising the steps of:
injecting a molten member of a housing into a forming die of the housing in condition that a bus bar formed with a conductive member of a plate shape is inserted in the forming die, and molding the housing;
mounting a semiconductor relay on the bus bar;
attaching a board having a circuit element mounted thereon to the housing; and
electrically connecting the semiconductor relay with the board by a wire, and connecting the semiconductor relay with a connector lead by a wire.

7. The electric connection box as claimed in claim 2, further comprising a wire, wherein one end of the wire is connected to the semiconductor relay, and the other end of the wire is connected to the board.

8. The electric connection box as claimed in claim 2, wherein the board and the bus bar are arranged on one plane each other.

9. The electric connection box as claimed in claim 3, wherein the board and the bus bar are arranged on one plane each other.

10. The electric connection box as claimed in claim 7, wherein the board and the bus bar are arranged on one plane each other.

11. The electric connection box as claimed in claim 2, wherein the bus bar is formed integrally with the housing.

12. The electric connection box as claimed in claim 3, wherein the bus bar is formed integrally with the housing.

13. The electric connection box as claimed in claim 7, wherein the bus bar is formed integrally with the housing.

14. The electric connection box as claimed in claim 4, wherein the bus bar is formed integrally with the housing.

15. The electric connection box as claimed in claim 8, wherein the bus bar is formed integrally with the housing.

16. The electric connection box as claimed in claim 9, wherein the bus bar is formed integrally with the housing.

17. The electric connection box as claimed in claim 10, wherein the bus bar is formed integrally with the housing.
